(19) United States
(12) Patent Application Publication
(10) Pub. No.: US 2002/0011649 A1
(43) Pub. Date: Jan. 31, 2002

(54) Fast bipolar transistor

(76) Inventor: Thierry Schwartzmann, Le Versoud (FR)

Correspondence Address: WOLF GREENFIELD & SACKS, PC, FEDERAL RESERVE PLAZA, 600 ATLANTIC AVENUE, BOSTON, MA, 02210-2211, US

(21) Appl. No.: 09/915,147

(22) Filed: Jul. 25, 2001

(30) Foreign Application Priority Data
Jul. 28, 2000 (FR) 00/09947

(51) Int. Cl. H01L 27/102

(52) U.S. Cl. 257/565

(57) ABSTRACT

A method of forming the collector area of a bipolar transistor on a semiconductor substrate, including the steps of forming an insulating trench delimiting an active region, selectively etching the semiconductor material of the active area, performing a selective epitaxy of the semiconductor material, and performing, during the selective epitaxy, a doping of the epitaxial material, this doping being modified during the growth of the epitaxial material.

### BACKGROUND OF THE INVENTION

1. Field of the Invention

The present invention relates to integrated circuits, and more specifically to fast integrated circuits formed on a semiconductor substrate.

2. Discussion of the Related Art

FIGS. 1A and 1B are cross-section views illustrating conventional steps of forming an NPN-type fast bipolar transistor and FIG. 1C is a top view of such a transistor.

In FIG. 1A, a lightly-doped P-type silicon substrate 1 has received a high-dose N⁺ ion implantation. This implantation is performed in a limited region 2, generally rectangular, located at the center of the location of the future transistor. After anneal and diffusion, the carriers of region 2 occupy a region 3. Region 3 has in cross-section a substantially semi-oval or semi-circular rounded shape at its periphery. Region 3 is intended for forming a buried collector layer which will be called hereafter a sub-collector and which is used to ensure the electric conduction between the lower collector surface and a collector contact, as will be indicated hereafter. A lightly-doped N-type silicon layer 4 has been formed by epitaxy on the substrate. Layer 4, which covers region 3, is intended for forming the transistor's collector.

During the next steps, the result of which is illustrated in FIG. 1B, a deep trench 6 is formed around the structure of the future transistor and delimits an active region. The trench is filled with silicon oxide. The trench is deep, to suppress possible lateral stray capacitances which could disturb the transistor operation. Trench 6 cuts the edges of region 3 and leaves in place, in active area 7, the central portion of region 3. At this stage, the transistor collector is formed. To limit stray capacitances, having portions of regions 3 outside of trench 6 should be avoided.

After this, a P-type base region 8 and an N-type emitter region 9 are formed in the active region. Before or after forming of regions 8 and 9, an N⁺-type region 10 intended for forming a collector contacting area and preferably extending to reach buried layer 3 will have been formed. Finally, emitter, base, and collector contacts E, B, and C are formed on respective regions 9, 8, and 10.

FIG. 1C is a very simplified cross-section view corresponding to the cross-section view of FIG. 1B. It includes a central active area delimited by a trench 6, and emitter, base, and collector contacts E, B, and C formed on base, emitter, and collector well regions 9, 8, and 10. Those skilled in the art should understand that the representation of FIGS. 1A to 1C is extremely simplified and is only intended for helping to understand the problem that the present invention aims at solving.

To increase the switching speed of a bipolar transistor, it is desired to decrease its stray capacitances, which is solved in the above example by creating the insulating peripheral trench.

It is also desired to reduce the transistor dimensions and to reduce as much as possible the transit time of the carriers in each of the transistor electrodes. It is well known to make very thin bases and the carrier transit time in the base is very short. However, the carrier transit time in the collector depends on the resistance in the path going from the collector metallization, via collector well 10 and sub-collector 3 under the intrinsic collector region arranged under emitter 9. Due to the rounded shape of the periphery of region 3, the doping of this region 3 appears to be lighter at its periphery. This tends to increase the resistance of this shallower (and less heavily-doped) portion of the sub-collector, and thus the resistance of a portion of the path of access to the collector. This problem is all the more acute as the transistor is of small dimension, that is, initial implantation area 2 from which the sub-collector region has been formed is small. Thus, in a structure of the type of that illustrated in FIGS. 1A to 1C, the more the conductivity, that is, the doping level of sub-collector 3, is desired to be increased, the more the corresponding region has to be spread out and thus the more the transistor dimensions have to be increased.

### SUMMARY OF THE INVENTION

An object of the present invention is to provide a particularly fast bipolar transistor.

Another object of the present invention is to provide a bipolar transistor combining fast switching speed with small dimensions.

To achieve these objects as well as others, the present invention provides a method of forming the collector area of a bipolar transistor on a semiconductor substrate, including the steps of:

a) forming an insulating trench delimiting an active region,

b) selectively etching the semiconductor material of the active area,

c) performing a selective epitaxy of the semiconductor material, and

d) performing, in step c), a doping of the epitaxial material, this doping being modified during the growth of the epitaxial material.

According to an embodiment of the present invention, the step of selective etching of the semiconductor material of the active region includes the step of forming an open mask in an internal region at the upper surface of the insulating trench.

According to an embodiment of the present invention, in step d), a first heavily-doped sub-layer of the conductivity type of the desired collector topped with a second lightly-doped sub-layer of the same conductivity type is formed.

According to an embodiment of the present invention, the semiconductor material of the substrate is silicon.

The present invention also aims at a bipolar transistor formed on a semiconductor substrate, including a collector surrounded with an insulating trench exhibiting, in a horizontal plane, a substantially uniform dopant concentration and, in a vertical direction, a desired concentration variation.

The foregoing objects, features and advantages of the present invention, will be discussed in detail in the following non-limiting description of specific embodiments in connection with the accompanying drawings.

### BRIEF DESCRIPTION OF THE DRAWINGS

FIGS. 1A and 1B, previously described, are cross-section views illustrating steps of manufacturing of a conventional fast bipolar transistor;

FIG. 1C, previously described, is a top view corresponding to the cross-section view of FIG. 1B;

FIGS. 2A to 2E are cross-section views illustrating steps of forming of a bipolar transistor according to the present invention; and

FIG. 3 shows a cross-section view according to a cross-section plane perpendicular to that of FIGS. 2A to 2E.

### DETAILED DESCRIPTION

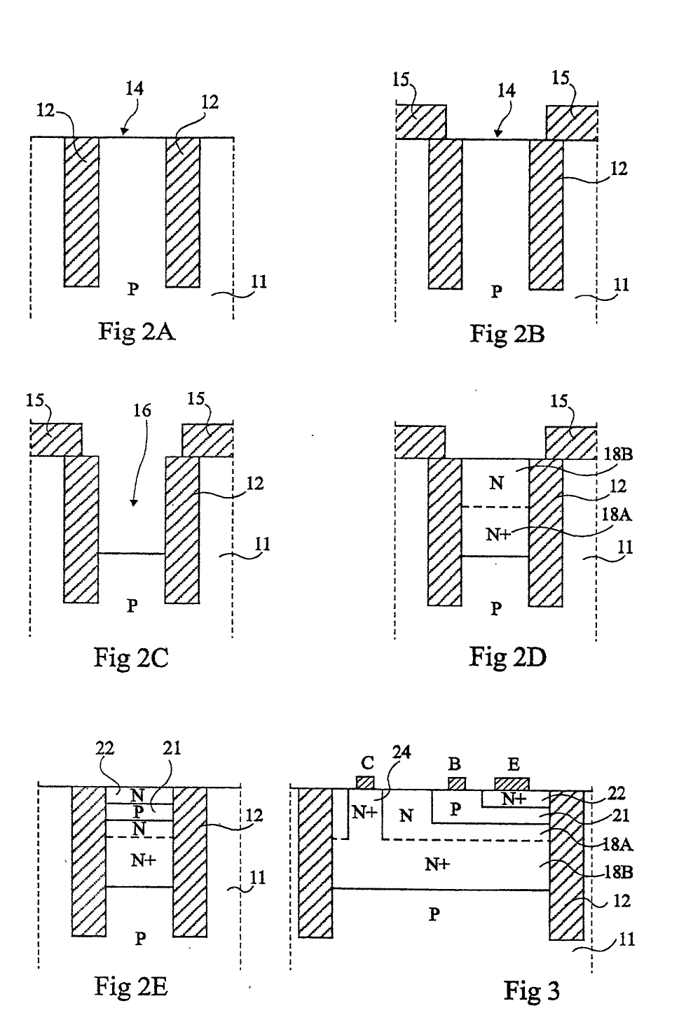

FIG. 2A shows a P-type semiconductor substrate 11 in which a trench 12 surrounds an active region 14. This trench, preferably deep to avoid parasitic effects, is filled with an insulating material, for example silicon oxide.

FIG. 2B illustrates a second step of the method according to the present invention. A mask 15, for example made of silicon oxide, is deposited on the substrate except for the location of active area 14. In FIG. 2B, mask 15 substantially stops in the middle of insulating region 12, but the mask could also stop at any point, for example at the edge, of trench 12.

FIG. 2C illustrates a third step of the method according to the present invention. The portion of silicon 14 surrounded with insulating trench 12 is removed by etching across a portion of the trench depth. This etching causes a depression 16. In the illustrated embodiment of the present invention, the depth of depression 16 is 2 μm and the trenches have a 3-μm depth.

At a next step, illustrated in FIG. 2D, silicon is deposited by selective epitaxy. Selective epitaxy means that the epitaxial silicon grows on silicon only. Thus, the epitaxial silicon only deposits from the bottom of depression 16 and forms an epitaxial silicon layer 18. Selective epitaxy methods are known by those skilled in the art and will not be discussed any further. Layer 18 is grown to reach the substrate surface, that is, the top of trenches 12.

Layer 18 is doped in-situ, that is, during its deposition, a dopant is introduced in gaseous form in the epitaxy reactor. Any chosen profile can thus be given to the doping of layer 18.

In a simplified manner, layer 18 will include a heavily-doped lower portion 18A corresponding to a sub-collector area and a lightly-doped upper portion 18B corresponding to an actual collector portion.

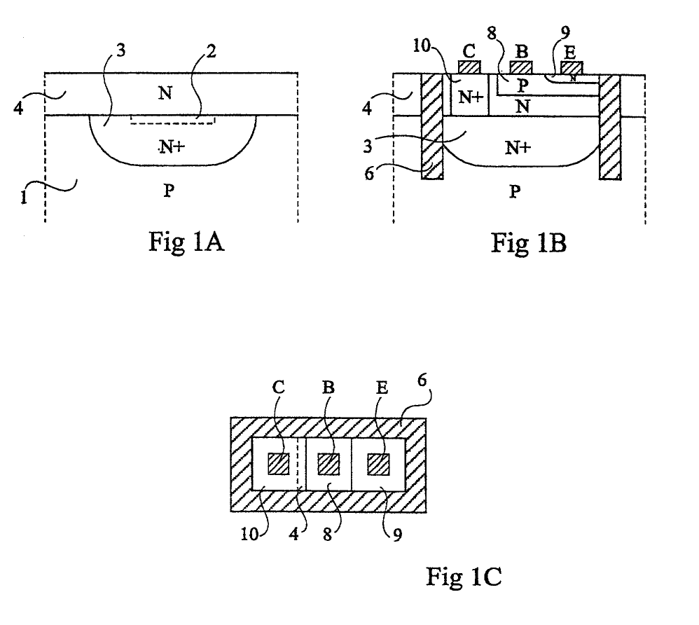

A result of this manufacturing method is that sub-collector 18A will have a uniform doping across its entire lateral extent, and especially that its doping level in the immediate vicinity of trench 12 will remain high. Further, the selective epitaxy requires no minimum dimension constraint to the device, whereas in the structure described in relation with FIG. 1, sub-collector layer 3 would impose dimensional limitations.

On the other hand, although it has been previously indicated that region 18 normally divides up into a heavily-doped sub-collector region 18A and a more lightly-doped actual collector region 18B, the transition profile between these two layers can be freely chosen.

At the step illustrated in FIG. 2E, a base layer 21 and an emitter region 22 are successively formed.

FIG. 3 is a cross-section view in a plane perpendicular to that of FIG. 2E and enables seeing the contact areas. The same regions are designated by same references. It also shows a heavily-doped N⁺-type well-collector region 24. According to the technology used, it will be a specific region or merely a diffusion performed at the same time as emitter region 22 and which will then not extend to region 18B but which will enable improving the contact ohmicity and reducing the access resistance access to the collector.

Another advantage of the method according to the present invention is its low thermal budget. Indeed, in the method of the present invention, there is no anneal step, as is the case in prior art (FIG. 1B). This is particularly advantageous in terms of compatibility with various technological processes, and in terms of cost.

Of course, the present invention is likely to have various alterations, modifications, and improvements which will readily occur to those skilled in the art. For example, the described transistor is an NPN transistor formed on a silicon substrate. It may of course be a PNP transistor, and the substrate may be a semiconductor material other than silicon.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method of forming a collector area of a bipolar transistor on a semiconductor substrate, including the steps of:
a) forming an insulating trench delimiting an active region,
b) selectively etching a semiconductor material of the active area,
c) performing a selective epitaxy of the semiconductor material, and
d) performing, in step c), a doping of the epitaxial material, this doping being modified during growth of the epitaxial material.

2. The method of claim 1, wherein the step of selective etching of the semiconductor material of the active region includes the step of forming an open mask in an internal region at the upper surface of the insulating trench.

3. The method of claim 1, wherein in step d), a first heavily-doped sub-layer of a conductivity type of the desired collector topped with a second lightly-doped sub-layer of a same conductivity type is formed.

4. The method of claim 1, wherein the semiconductor material of the substrate is silicon.

5. A bipolar transistor formed on a semiconductor substrate, including a collector surrounded with an insulating trench exhibiting, in a horizontal plane, a substantially uniform dopant concentration and, in a vertical direction, a desired concentration variation.
